(19) United States
(12) Patent Application Publication
(10) Pub. No.: US 2020/0043785 A1
(43) Pub. Date: Feb. 6, 2020

(54) A CONTACT STRUCTURE HAVING A FIRST LINER AND A SECOND LINER FORMED BETWEEN A CONDUCTIVE ELEMENT AND A INSULATING LAYER

(71) Applicant: Winbond Electronics Corp., Taichung City (TW)

(72) Inventors: Huang-Nan CHEN, Taichung City (TW); Noriaki IKEDA, Taichung City (TW)

(21) Appl. No.: 16/050,233

(22) Filed: Jul. 31, 2018

(51) Int. Cl. H01L 21/768; H01L 23/528; H01L 23/535

(52) U.S. Cl. CPC H01L 21/76895; H01L 23/5283; H01L 23/535; H01L 27/105; H01L 21/76846; H01L 21/76865; H01L 21/76805

(57) ABSTRACT

A contact structure and a method for forming the contact structure are provided. The contact structure includes an insulating layer formed on a substrate. The contact structure includes a conductive element formed on the substrate and in the insulating layer. The contact structure includes a first liner formed in the insulating layer and on sidewalls of an upper portion of the conductive element. The contact structure includes a second liner formed on the sidewalls of the conductive element. A conductive contact plug is formed by the second liner and the conductive element. At the upper portion of the conductive element, the second liner is interposed between the conductive element and the first liner. At the lower portion of the conductive element, the second liner is interposed between the conductive element and the insulating layer.

### BACKGROUND

### Field of the Disclosure

The present disclosure relates to a memory device, and in particular it relates to a memory device having a contact structure and a method for manufacturing the memory device.

### Description of the Related Art

With the increasing popularity of portable electronic products, consumer demand for memory devices is also increasing. All portable electronic products (such as digital cameras, notebook computers, mobile phones, etc.) need a lightweight and reliable memory device for the storage and transmission of data.

With the trend of miniaturization of electronic products, there is also demand for the miniaturization of memory devices. However, with the miniaturization of memory devices, it becomes more difficult to improve the performance, yield, and reliability of the product. Therefore, there is still a demand for memory devices having high performance, high durability, high yield, and high reliability, and a method of forming the same.

### BRIEF SUMMARY

The disclosure provides a contact structure. The contact structure includes an insulating layer formed on a substrate. The contact structure includes a conductive element formed on the substrate and in the insulating layer. The contact structure includes a first liner formed in the insulating layer and on sidewalls of an upper portion of the conductive element. The contact structure includes a second liner formed on the sidewalls of the conductive element. A conductive contact plug is formed by the second liner and the conductive element. At the upper portion of the conductive element, the second liner is interposed between the conductive element and the first liner. At the lower portion of the conductive element, the second liner is interposed between the conductive element and the insulating layer.

The disclosure also provides a method for forming a contact structure. The method includes forming an insulating layer on a substrate. The method includes performing a first etching process to form a contact hole in the insulating layer. The method includes conformally forming a first liner material on sidewalls and a bottom of the contact hole. The method includes performing a second etching process to remove the first liner material on the bottom of the contact hole and to increase a depth of the contact hole. The first liner material remaining on the sidewalls of the contact hole forms a first liner. The method includes forming a second liner on the sidewalls and the bottom of the contact hole. The method includes filling a conductive material into the contact hole to form a conductive element on the substrate and in the insulating layer. The second liner and the conductive element form a conductive contact plug. The second liner is interposed between the conductive element and the first liner at an upper portion of the conductive element. The second liner is interposed between the conductive element and the insulating layer at a lower portion of the conductive element.

The disclosure also provides a memory device. The memory device includes an array region and a peripheral region. The memory device also includes at least one contact structure as described above, and the at least one contact structure is disposed in the peripheral region.

A detailed description is given in the following embodiments with reference to the accompanying drawings.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1H show cross-sectional views of various stages of manufacturing a memory device in accordance with some embodiments;

FIG. 2 shows a cross-sectional view of one stage of manufacturing a memory device in accordance with other embodiments; and

FIG. 3 shows a cross-sectional view of one stage of manufacturing a memory device in accordance with another embodiment.

### DETAILED DESCRIPTION

The present disclosure is best understood from the following detailed description when read with the accompanying figures. It should be noted that, in accordance with the standard practice in the industry, various features are not drawn to scale. In fact, the relative dimensions of the various features may be arbitrarily increased or reduced for clarity of discussion. In addition, the present disclosure may repeat reference numerals and/or letters in the various examples. This repetition is for the purpose of simplicity and clarity and does not in itself dictate a relationship between the various embodiments and/or configurations discussed.

In this disclosure, the term “about” or “approximately” means in a range of 20% of a given value or range, preferably 10%, and more preferably 5%. In this disclosure, if there is no specific explanation, a given value or range means an approximate value which may imply the meaning of “about” or “approximately”.

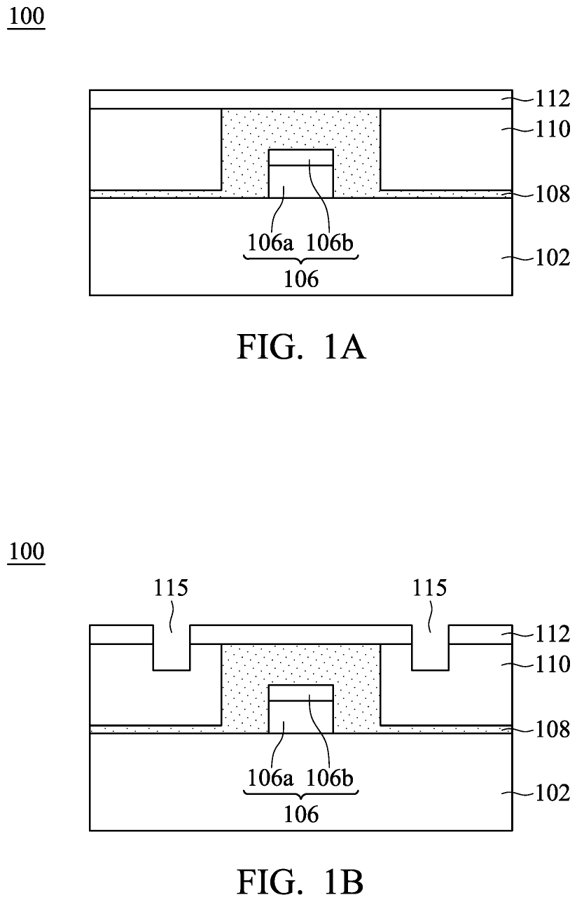

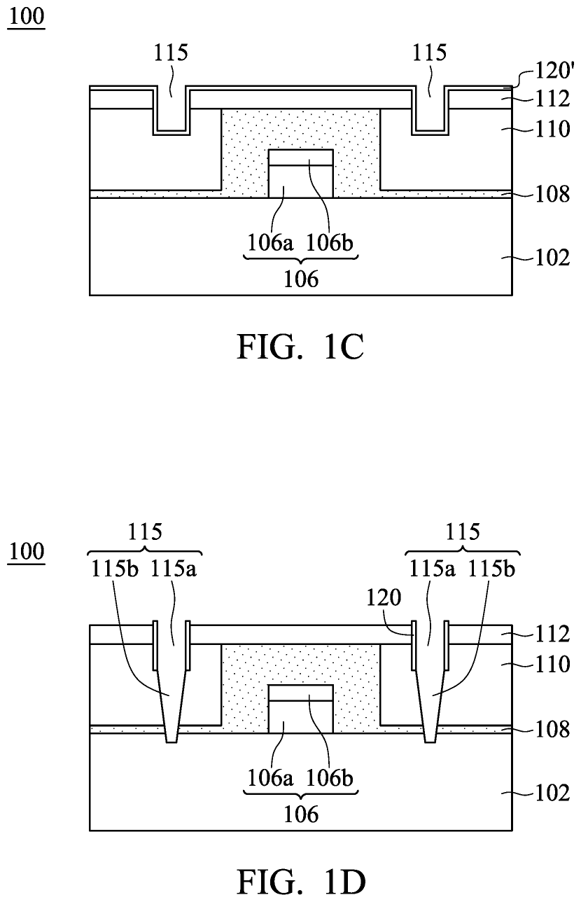

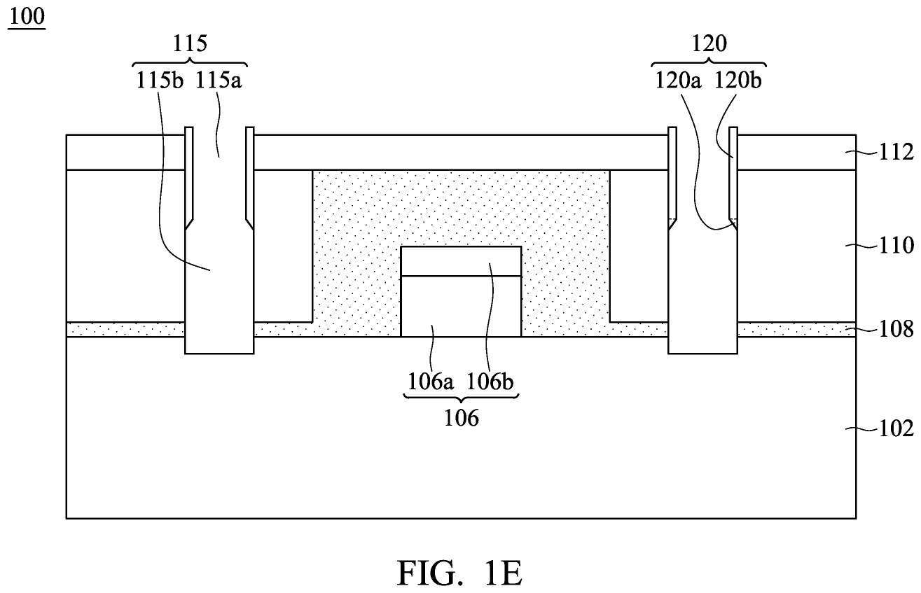

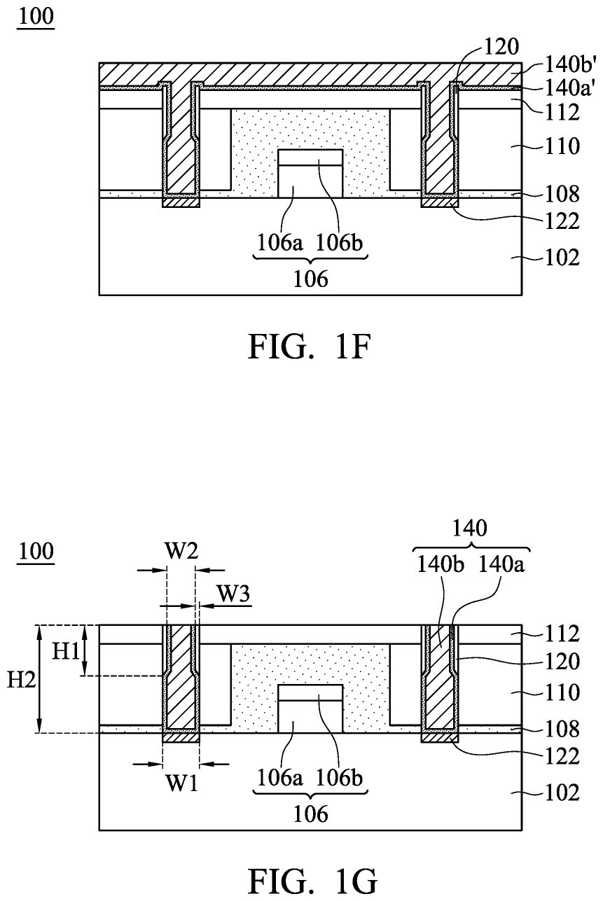

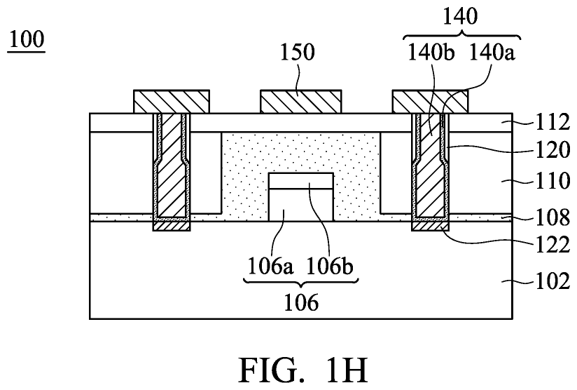

In some embodiments of this disclosure, a memory device and a method for manufacturing the memory device are provided. More specifically, in some embodiments of this disclosure, a contact structure included in a memory device and its forming method are provided. FIGS. 1A-1H show cross-sectional views of various stages of manufacturing a memory device 100 in accordance with some embodiments.

Referring to FIG. 1A, the memory device 100 includes a substrate 102, and the substrate 102 includes an array region and a peripheral region. In order to simplify the description, only the peripheral region of the memory device 100 is shown in FIGS. 1A-1H, and the array region is omitted. However, such omissions are for convenience of explanation and are not intended to be limiting. In this embodiment, the contact structures described hereinafter are formed in the peripheral region. In some embodiments, the contact structures may be formed in the array region. In other embodiments, the contact structures may be formed in both the array region and the peripheral region.

Referring to FIG. 1A, in the peripheral region, a gate structure 106 is formed on the substrate 102. In this embodiment, the gate structure 106 includes a polycrystalline silicon gate 106a and a metal gate 106b stacked on the polycrystalline silicon gate 106a. It should be understood that FIG. 1A has been simplified. FIG. 1A may include other components not shown, such as shallow trench isolation structures, gate dielectric layers, or other components which may be included in the memory device.

The material of the substrate 102 may include silicon, silicon-containing semiconductor, silicon on insulator (SOI), another applicable material, or a combination thereof. The material of the metal gate 106b may include, for example, tungsten, aluminum, copper, gold, silver, tantalum, hafnium, zirconium, an alloy thereof, or another applicable metal material. For example, after depositing the polycrystalline silicon layer and the metal layer in sequence, the polycrystalline silicon layer and the metal layer are patterned. As a result, the gate structure 106 is formed.

Then, a spacer layer 108 is formed on the substrate 102, and the spacer layer 108 conformally covers the sidewalls and the top portion of the gate structure 106. The material of the spacer layer may include, for example, a nitride, an oxide, an oxynitride, another suitable insulating material, or a combination thereof. In this embodiment, the spacer layer 108 is a single layer structure, and the spacer layer 108 is a nitride layer. In other embodiments, the spacer layer 108 is a dual-layer structure or a multilayer structure.

Then, a first insulating layer 110 is formed on the substrate 102 to completely cover the substrate 102 and the spacer layer 108. Next, a planarization process is performed to expose the top surface of the spacer layer 108. The material of the first insulating layer 110 may include an oxide, an oxynitride, another suitable insulating material, or a combination thereof. It should be noted that the material of the first insulating layer 110 is different from the material of the spacer layer 108 in order to facilitate subsequent processes. In this embodiment, the spacer layer 108 is a nitride (e.g., silicon nitride), and the first insulating layer 110 is an oxide (e.g., silicon oxide).

Still referring to FIG. 1A, then, a second insulating layer 112 may be deposited on the substrate 102 optionally. The material of the second insulating layer 112 may be the same as or different from the material of the first insulating layer 110. During the subsequent process, the second insulating layer 112 can protect the spacer layer 108 in the array region (not shown) from damage. In other embodiments, an additional protective layer (not shown) may be formed on the array region during subsequent processing, and the second insulating layer 112 formed in the peripheral region may be omitted.

Referring to FIG. 1B, a first etching process is performed to form a contact hole 115 in the first insulating layer 110 and the second insulating layer 112. The first etching process may include a dry etching process, a wet etching process, or a combination thereof.

Referring to FIG. 1C, then, the first liner material 120′ is conformally formed on the second insulating layer 112 and in the contact hole 115. More specifically, the first liner material 120′ is formed on the bottom and sidewalls of the contact hole 115. The process of forming the first liner material 120′ may include a physical vapor deposition process, a chemical vapor deposition process, an atomic layer deposition process, another suitable deposition process, or a combination thereof. The first liner material 120′ may include a nitride, an oxynitride, a carbide, a polycrystalline silicon, another suitable insulating material, or a combination thereof. In this embodiment, the first liner material 120′ is silicon nitride.

Referring to FIG. 1D, then, a second etching process is performed to remove the first liner material 120′ on the bottom of the contact hole 115 and to increase the depth of the contact hole 115. The second etching process may be an anisotropic etching process. More specifically, the second etching process may be a two-step etching process. In the first step of the second etching process, the first liner material 120′ on the bottom of the contact hole 115 is removed and the first liner material 120′ on the sidewall of the contact hole 115 remains. In the second step of the second etching process, the first insulating layer 110 under the contact hole 115 is removed to increase the depth of the contact hole 115.

Referring to FIG. 1D, after the second etching process, the first liner material 120′ remaining on the sidewalls of the contact hole 115 forms a first liner 120. After the second etching process, the contact hole 115 may be divided into a lower portion 115b and an upper portion 115a. The upper portion 115a has a substantially uniform width from the top to the bottom, and the lower portion 115b has a tapered width that tapers from the top to the bottom.

Then, at least one wet process is performed. The wet processes may include wet cleaning processes and wet etching processes. The function of the conductive contact plug which will be formed subsequently is to provide an electrical connection. If the insulating material exists at the interface between the conductive contact plug and the substrate 102 (or the metal silicide layer), the electrical resistance value between the conductive contact plug and the substrate 102 (or the conductive contact plug and the metal silicide layer) may be greatly increased, and the operating voltage may be also increased. As a result, the energy consumption of the memory device is increased, and the performance and durability of the memory device are reduced. In order to prevent the insulating material from remaining on the surface of the substrate 102 (or the metal silicide layer), at least one wet cleaning process may be performed in subsequent processes to remove the insulating material. Furthermore, since the aspect ratio is high, the width of the lower portion 115b of the contact hole 115 narrows gradually from the top to the bottom. Therefore, the interface area between the conductive contact plug and the substrate 102 is too small, and the electrical resistance value is too high. In order to increase the interface area, a wet etching process may be performed optionally before forming the metal silicide.

After the wet process described above, the width of the lower portion 115b of the contact hole 115 is increased, and the lower portion 115b of the contact hole 115 has a substantially uniform width from the top to the bottom, as shown in FIG. 1E.

Referring to FIG. 1F, a metal material is deposited on the bottom of the contact hole 115, and a metal silicidation process is performed. In the metal silicidation process, the metal material and the silicon of the substrate 102 undergo the silicidation reaction at a high temperature to form a metal silicide layer 122 at the bottom of the contact hole 115. The metal material may include cobalt, nickel, tungsten, another suitable metal material, or a combination thereof.

Then, a second liner material 140a′ is conformally formed on the second insulating layer 112 and in the contact hole 115. As shown in FIG. 1F, the second liner material 140a′ is formed on the sidewalls and the bottom of the contact hole 115. The second liner material 140a′ can comprise a metal, an alloy, a metal nitride, another conductive material, or a combination thereof. In some embodiments, the second liner material 140a′ includes titanium, tantalum, titanium nitride or tantalum nitride. The process for forming the second liner material 140a′ may include a chemical vapor deposition process, an atomic layer deposition process, another suitable deposition process, or a combination thereof.

Still referring to FIG. 1F, then, a conductive material 140b′ is formed on the second insulating layer 112 and filled into the contact hole 115. The conductive material 140b′ may include a metal, such as tungsten, aluminum, copper, gold, silver, another suitable metallic material, or a combination thereof. The process for forming the conductive material 140b′ may include a physical vapor deposition process, a chemical vapor deposition process, an atomic layer deposition process, another suitable deposition processes, or a combination thereof.

The adhesion between the conductive material 140b′ and the insulating layer (for example, the first insulating layer 110, the second insulating layer 112, and the first liner 120) is not good. By forming the second liner 140a, the adhesion between the conductive material 140b′ and the insulating layer can be improved, and delamination of the conductive material 140b′ can be avoided. As a result, the yield of the memory device 100 can be improved.

Referring to FIG. 1G then, a planarization process is performed to remove a portion of the second insulating layer 112, a portion of the first liner 120, a portion of the second liner material 140a′, and a portion of the conductive material 140b′, and a second liner 140a and a conductive element 140b are formed in the contact hole 115. In this embodiment, the conductive contact plug 140 is formed by the second liner 140a and the conductive element 140b. Therefore, in this specification, the second liner 140a and the conductive element 140b are collectively referred to as a conductive contact plug 140. After the planarization process, the top surface of the second insulating layer 112, the top surface of the first liner 120, and the top surface of the conductive contact plug 140 are coplanar.

Referring to FIG. 1G the first liner 120 is formed on the sidewalls of the upper portion of the conductive element 140b. In some embodiments, the first liner 120 surrounds the upper portion of the conductive element 140b. Furthermore, at the upper portion of the conductive element 140b, the second liner 140a is interposed between the conductive element 140b and the first liner 120. In addition, at the lower portion of the conductive element 140b, the second liner 140a is interposed between the conductive element 140b and the first insulating layer 110. In other words, there are two lining layers at the upper portion of the conductive element 140b and only one lining layer at the lower portion of the conductive element 140b.

Referring to FIG. 1H, a conductive line 150 is formed on the second insulating layer 112. The conductive line 150 may electrically connect the conductive contact plug 140 to other components of the memory device 100 or an external circuit. For example, the conductive trace 150 may be formed by depositing a conductive material on the substrate 102 and patterning the conductive material thereafter. The conductive material used to form the conductive line 150 may include a metal, such as aluminum, copper, gold, silver, tungsten, another suitable metallic material, or a combination thereof. The deposition process for forming the conductive line 150 may include a physical vapor deposition process, an atomic layer deposition process, a sputtering process, another suitable deposition process, or a combination thereof. In some embodiments, the conductive material 140b′ includes copper.

In general, when a hole having a high aspect ratio (for example, an aspect ratio greater than 4) is formed, the width of the hole gradually narrows from the top to the bottom. As described above, if the interface area between the contact hole 115 and the substrate 102 (or the metal silicide layer 122) is too small, the aforementioned problem due to the excessively high electrical resistance value may occur. The smaller the size of the memory device, the higher the aspect ratio of the hole. Therefore, with the miniaturization of the memory device, the aforementioned problem caused by the excessively high electrical resistance value will become more serious.

In order to avoid the aforementioned problem, the wet etching process that was described above may be performed to increase the width of the bottom portion of the contact hole 115. However, as a result, the width of the top portion of the contact hole 115 also increases. When the conductive contact plug 140 is formed in such a contact hole 115 (i.e., a contact hole having an enlarged top width), the distance (the distance in the horizontal direction) between the top portion of the conductive contact plug 140 and the adjacent conductive line 150 (e.g., the conductive line 150 in the middle of the FIG. 1H) may become shorter. Therefore, the conductive contact plug 140 and the adjacent conductive line 150 may be short-circuited, and the operational errors of the memory device 100 may occur. As a result, the yield and reliability of the memory device 100 will be greatly reduced.

Furthermore, if the offset or deviation occurs when the conductive line 150 is patterned, the distance between the conductive contact plug 140 and the adjacent conductive line 150 may be further shortened, and the aforementioned problem caused by the short-circuit will become more serious.

On the other hand, in order to ensure that the insulating material does not remain on the surface of the substrate 102 (or the metal silicide layer 122), at least one of the wet cleaning processes described above may be performed. All of these wet cleaning processes have the ability to remove the insulating material (e.g., the first insulating layer 110 or the second insulating layer 112). In other words, these wet cleaning processes can also increase the width of the contact hole 115. Therefore, even if no additional wet etching process is performed, the aforementioned problem due to the short-circuit may still occur. The smaller the size of the memory device, the shorter the distance between the conductive contact plug 140 and the adjacent conductive line 150. Therefore, with the miniaturization of the memory device, the aforementioned problem caused by the short-circuit will become more serious.

In order to simultaneously solve or avoid the aforementioned problem caused by the excessively high electrical resistance value and the aforementioned problem caused by the short-circuit, a method of forming a contact structure is provided in some embodiments of this disclosure.

Referring to FIG. 1D, the first liner 120 is formed on the sidewalls of the contact hole 115, and then the second etching process is performed. The resulting contact hole 115 has a lower portion 115b and an upper portion 115a. The first liner 120 is located on the sidewalls of the upper portion 115a, but is not located on the sidewalls of the lower portion 115b. In a subsequent wet process (e.g., a wet cleaning process and/or a wet etching process), the first liner 120 can protect the upper portion 115a, and the width of the upper portion 115a will not be enlarged. In this way, the problem caused by the short-circuit can be solved or avoided. On the other hand, there is no first liner 120 located on the sidewalls of the lower portion 115b. Therefore, in the subsequent wet process, the width of the lower portion 115b is enlarged, as shown in FIG. 1E. In this way, the problem caused by the excessively high electrical resistance value can be solved or avoided.

In addition, because the contact structure described above is included, the performance, durability, yield, and reliability of the resulting memory device 100 can be greatly improved.

In order to avoid an increase in the width of the upper portion 115a, the selectivity of the first insulating layer 110 (and/or the second insulating layer 112) to the first liner layer 120 in each of the wet processes described above may be increased. In at least one of the wet processes described above, the removal rate (etching rate) of the first insulating layer 110 (and/or the second insulating layer 112) is R1, and the removal rate (etching rate) of the first liner layer 120 is R2. Therefore, the ratio of the removal rate (etching rate) of the first insulating layer 110 (and/or the second insulating layer 112) to the first liner layer 120 is R1/R2. In some embodiments, R1/R2 is 10-100 in at least one of the wet processes described above. In other embodiments, R1/R2 is 20-80 in at least one of the wet processes described above. In still other embodiments, R1/R2 is 30-60 in at least one of the wet processes described above. After the wet process described above, the top surface of the first liner 120 is higher than the top surface of the second insulating layer 112, as shown in FIG. 1E.

Referring to FIG. 1G the top surface of the conductive contact plug 140 has a second width W2, and the top surface of the first liner 120 has a third width W3. If the ratio of the second width W2 to the third width W3 is too small, it means that the width of the contact hole 115 has become too small, and the aspect ratio of the contact hole 115 has become too high. Therefore, it becomes difficult to fill the conductive material 140b′ into the contact hole 115. As a result, voids may be formed in the conductive contact plug 140 easily, and the yield and reliability of the memory device 100 may be reduced. If the third width W3 is too large (i.e., the thickness of the first liner 120 is too large), a similar problem will occur. In contrast, if the ratio of the second width W2 to the third width W3 is too large, the thickness of the first liner 120 is too small, and the width of the upper portion 115a cannot be prevented from being enlarged in the wet process described above. As a result, the aforementioned problem caused by the short-circuit may occur. Moreover, if the ratio of the second width W2 to the third width W3 is too large, the distance between the conductive contact plug 140 and the adjacent conductive line 150 may be too small. As a result, the aforementioned problem caused by the short-circuit may also occur.

Therefore, the width of the top surface of the first liner 120 may be controlled within a specific range. As shown in FIG. 1G the top surface of the first liner 120 has a third width W3. In some embodiments, the third width W3 is 3-10 nm. In other embodiments, the third width W3 is 4-9 nm. In still other embodiments, the third width W3 is 5-8 nm. Furthermore, the ratio of the second width W2 to the third width W3 may be controlled within a specific range. In some embodiments, the ratio W2/W3 of the second width W2 to the third width W3 is 5-40. In other embodiments, the ratio W2/W3 of the second width W2 to the third width W3 is 10-30. In still other embodiments, the ratio W2/W3 of the second width W2 to the third width W3 is 15-20.

Referring to FIG. 1G the bottom surface of the conductive contact plug 140 has a first width W1, and the top surface of the conductive contact plug 140 has a second width W2. In this embodiment, the first width W1 is greater than the second width W2. Furthermore, if the ratio of the first width W1 to the second width W2 is too small, the first width W1 may not be large enough. Therefore, the contact area between the conductive contact plug 140 and the substrate 102 (or the metal silicide layer 122) cannot be greatly increased. As a result, the aforementioned problem caused by the excessively high electrical resistance value cannot be solved. In contrast, if the ratio of the first width W1 to the second width W2 is too large, the difference between the first width W1 and the second width W2 is too large. Therefore, it becomes difficult to fill the second liner material 140a′ and the conductive material 140b′ into the contact hole 115. As a result, voids may be formed in the conductive contact plug 140 easily, and the yield and reliability of the memory device 100 may be reduced. Moreover, if the ratio of the first width W1 to the second width W2 is too large, the first width W1 may become too large. Therefore, there will be too much available area of the substrate being occupied. It is disadvantageous for the miniaturization of the memory device.

Therefore, the ratio of the first width W1 to the second width W2 may be controlled within a specific range. In some embodiments, the ratio W 1/W2 of the first width W1 to the second width W2 is 1.1-1.4. In other embodiments, the ratio W1/W2 of the first width W1 to the second width W2 is 1.1-1.3. In still other embodiments, the ratio W1/W2 of the first width W1 to the second width W2 is 1.1-1.2.

Referring to FIG. 1G the first liner 120 has a first height H1, and the conductive contact plug 140 has a second height H2. If the ratio of the first height H1 to the second height H2 is too small, the depth of the upper portion 115b of the contact hole 115 with a smaller width is too small. Therefore, the distance between the lower portion of the resulting conductive contact plug 140 and the adjacent conductive line 150 may be too small. As a result, the aforementioned problem caused by the short-circuit may occur. In contrast, if the ratio of the first height H1 to the second height H2 is too large, the amount of the conductive material filled into the contact hole 115 becomes small. As a result, it is disadvantageous to reduce the electrical resistance value between the conductive contact plug 140 and the substrate 102. Moreover, if the insulating first liner 120 extends to the surface of the substrate 102, the contact area between the conductive contact plug 140 and the substrate 102 is reduced. It is disadvantageous to reduce the electrical resistance value between the conductive contact plug 140 and the substrate 102.

Therefore, the ratio of the first height H1 to the second height H2 may be controlled within a specific range. In some embodiments, the ratio H1/H2 of the first height H1 to the second height H2 is 0.1-0.8. In other embodiments, the ratio H1/H2 of the first height H1 to the second height H2 is 0.3-0.7. In still other embodiments, the ratio H1/H2 of the first height H1 to the second height H2 is 0.4-0.6.

In addition, referring to FIG. 1E, the cross-sectional profile of the first liner 120 includes a lower portion 120a and an upper portion 120b. The upper portion 120b of the first liner 120 extends downward from the top surface of the first liner 120, and the upper portion 120b is substantially perpendicular to the top surface of the second insulating layer 112. The lower portion 120a of the first liner 120 is adjacent to the upper portion 120b and extends to the sidewalls of the first insulating layer 110 along an oblique direction. In other words, in this embodiment, the lower portion 120a of the first liner 120 narrows gradually toward the lower side. Such a cross-sectional profile of the first liner layer 120 allows the second liner layer 140a to be more easily formed on the inner sidewalls of the contact hole 115. Furthermore, if the sidewalls of the lower portion 120a of the first liner 120 are perpendicular to the sidewalls of the upper portion 120b, the second liner 140a may create a discontinuous portion at the interface between the lower portion 120a and the upper portion 120b. Since there is no second liner 140a, delamination of the conductive element may occur here. Therefore, the yield of the memory device 100 may be reduced.

In contrast, in this embodiment, the lower portion 120a of the first liner 120 narrows gradually in an oblique direction. Therefore, the resulting second liner layer 140a may be a continuous film layer without discontinuous portions. As a result, the yield of the memory device 100 can be further solved.

A memory device is provided in some embodiments of this disclosure. Referring to FIG. 1H, the memory device 100 of this disclosure may include the substrate 102 having an array region and a peripheral region. The memory device 100 also includes the gate structure 106 and the spacer layer 108 formed on the substrate 102. The spacer layer 108 conformally covers the sidewalls and the top portion of the gate structure 106. The memory device 100 also includes a contact structure located in the peripheral region. The contact structure includes the first insulating layer 110 and the second insulating layer 112 formed on the substrate 102. The contact structure also includes the conductive contact plug 140 formed on the substrate 102 and located in the first insulating layer 110 and the second insulating layer 112. The conductive contact plug 140 is formed by the conductive second liner 140a and the conductive element 140b. The contact structure also includes an insulating first liner 120 in the first insulating layer 110 and the second insulating layer 112. The first liner 120 surrounds and directly contacts the upper portion of the conductive contact plug 140. More specifically, the first liner 120 surrounds the upper portion of the conductive element 140b. Furthermore, at the upper portion of the conductive element 140b, the second liner 140a is interposed between the conductive element 140b and the first liner 120. In addition, at the lower portion of the conductive element 140b, the second liner 140a is interposed between the conductive element 140b and the first insulating layer 110. In other words, there are two lining layers at the upper portion of the conductive element 140b and only one lining layer at the lower portion of the conductive element 140b.

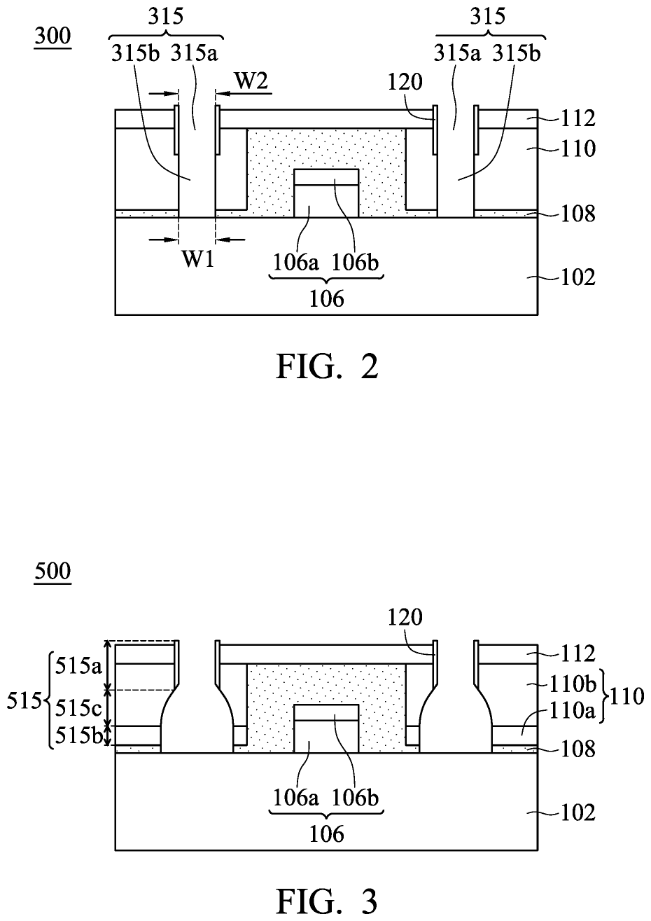

FIG. 2 shows a cross-sectional view of one stage of manufacturing a memory device 300 in accordance with other embodiments. FIG. 2 is similar to FIG. 1E, and the difference is that the contact hole 315 shown in FIG. 2 has a substantially uniform width from the top to the bottom. The same components shown in FIG. 2 and FIG. 1E are denoted by the same reference numerals. In order to simplify the description, the components which are the same as the components shown in FIG. 1E and the steps for forming them are not repeated here. Furthermore, after the structure shown in FIG. 2 is formed, the processes of FIGS. 1F-1H described above may be performed. In order to simplify the description, the processes of FIGS. 1F-1H will not be repeated here.

Referring to FIG. 2, in this embodiment, by forming the first liner 120 on the sidewalls of the upper portion 315a of the contact hole 315, the upper portion 315a and the lower portion 315b of the contact hole 315 may have a substantially uniform width. Therefore, the first width W1 of the bottom surface of the resulting conductive contact plug 140 can be made equal to the second width W2 of the top surface of the conductive contact plug 140. As a result, the performance, durability, yield, and reliability of the memory device 300 can be greatly improved. Furthermore, in this embodiment, the first width W1 does not become too large. Therefore, there will not be too much available area of the substrate being occupied, and it is advantageous for the miniaturization of the memory device.

FIG. 3 shows a cross-sectional view of one stage of manufacturing a memory device 500 in accordance with other embodiments. FIG. 3 is similar to FIG. 1E, and the difference is that the first insulating layer 110 includes two sub-layers. The same components shown in FIG. 3 and FIG. 1E are denoted by the same reference numerals. In order to simplify the description, the components which are the same as the components shown in FIG. 1E and the steps for forming them are not repeated here. Furthermore, after the structure shown in FIG. 3 is formed, the processes of FIGS. 1F-1H described above may be performed. In order to simplify the description, the processes of FIGS. 1F-1H will not be repeated here.

Referring to FIG. 3, before filling the second liner material 140a′ and the conductive material 140b′, the cross-sectional profile of the contact hole 515 may include a first portion 515a, a second portion 515b, and a third portion 515c. The first portion 515a extends downward from the top portion of the contact hole 515. The second portion 515b extends upward from the bottom portion of the contact hole 515. The third portion 515c is formed between the first portion 515a and the second portion 515b and is adjacent to the first portion 515a and the second portion 515b. The third portion 515c tapers toward the first portion 515a. The cross-sectional profile of the subsequently formed conductive contact plug 140 is the same as the cross-sectional profile of the contact hole 515. More specifically, in this embodiment, the cross-sectional profile of the conductive contact plug 140 includes a first portion, a second portion, and a third portion. The first portion extends downward from the top surface of the conductive contact plug 140. The second portion extends upward from the bottom surface of the conductive contact plug 140. The third portion is formed between the first portion and the second portion and is adjacent to the first portion and the second portion. Furthermore, the third portion tapers toward the first portion.

Referring to FIG. 3, the first insulating layer 110 includes a first sub-layer 110a and a second sub-layer 110b formed on the first sub-layer 110a. The interface of the first sub-layer 110a and the second sub-layer 110b is substantially level with the interface of the second portion 515b and the third portion 515c. In this embodiment, the material of the first sub-layer 110a is different from the material of the second sub-layer 110b. Therefore, in at least one of the wet processes described above, the etching rate of the first sub-layer 110a is different from the etching rate of the second sub-layer 110b. As a result, the cross-sectional profiles of the contact hole 515 corresponding to the first sub-layer 110a and that corresponding to the second sub-layer 110b are also different from each other. More specifically, referring to FIG. 3, after the wet processes described above, the first sub-layer 110a has a substantially uniform width, and the second sub-layer 110b has a width that gradually narrows downward. The cross-sectional profile of the contact hole 515 is determined by the cross-sectional profile of the first insulating layer 110, and the cross-sectional profile of the contact hole 515 and the cross-sectional profile of the first insulating layer 110 are complementary to each other. Therefore, the third portion 515c of the contact hole 515 has a cross-sectional profile that tapers upwardly. In other words, the cross-sectional profile of the contact hole 515 may be adjusted to a desired shape as needed by selecting suitable materials to form the first sub-layer 110a and the second sub-layer 110b. Therefore, the flexibility of the process can be improved. The first sub-layer 110a and the second sub-layer 110b may independently include an oxide, an oxynitride or another suitable insulating material, and the material of the first sub-layer 110a is different from the material of the second sub-layer 110b. In some embodiments, the first sub-layer 110a and the second sub-layer 110b may include a first oxide and a second oxide, respectively, and the first oxide and the second oxide are respectively formed by different processes. In other embodiments, the first sub-layer 110a may include a spin-on oxide, and the second sub-layer 110b may include a high density plasma oxide (HDP oxide). The number of the sub-layers of the first insulating layer 110 shown in FIG. 3 is merely for illustrative purposes and is not intended to be limiting. In other embodiments, the first insulating layer 110 may include three or more sub-layers.

The cross-sectional profile of the sidewalls of the third portion 515c includes a rounded and curved portion, and thus may be more advantageous to fill the second liner material 140a′ and the conductive material 140b′ into the contact hole 515. Furthermore, the amount of conductive material filled into the contact hole 515 is increased. As a result, the electrical resistance value of the conductive contact plug 140 can be further reduced, and the performance and durability of the memory device 500 can be further improved.

The cross-sectional profiles of the contact holes shown in FIG. 2 and FIG. 3 are merely for illustrative purposes and are not intended to be limiting. In some embodiments, the cross-sectional profile of the lower portion of the contact hole may be linear, curved, serrated, irregular, or a combination thereof.

In conclusion, some embodiments in this disclosure provide a contact structure and a method of forming the same. Furthermore, some embodiments in this disclosure provide a memory device including the contact structure, and the performance, durability, yield, and reliability of the memory device can be significantly improved.

Although the disclosure has been described by way of example and in terms of the preferred embodiments, it should be understood that various modifications and similar arrangements (as would be apparent to those skilled in the art) can be made herein without departing from the spirit and scope of the disclosure as defined by the appended claims.

1. A contact structure, comprising:
an insulating layer formed on a substrate;
a conductive element formed on the substrate and in the insulating layer;
a first liner formed in the insulating layer and on sidewalls of an upper portion of the conductive element; and
a second liner formed on the sidewalls of the conductive element, wherein the second liner and the conductive element form a conductive contact plug, wherein the second liner is interposed between the conductive element and the first liner at the upper portion of the conductive element, and wherein the second liner is interposed between the conductive element and the insulating layer at a lower portion of the conductive element, and wherein a horizontal bottom portion of the second liner is interposed between the conductive element and the substrate.

2. The contact structure as claimed in claim 1, wherein a bottom surface of the conductive contact plug has a first width W1, wherein a top surface of the conductive contact plug has a second width W2, and wherein the first width W1 is greater than or equal to the second width W2.

3. The contact structure as claimed in claim 2, wherein a ratio W1/W2 of the first width W1 to the second width W2 is 1.1-1.4.

4. The contact structure as claimed in claim 1, wherein a cross-sectional profile of the conductive contact plug comprises:
a first portion extending downward from a top surface of the conductive contact plug;
a second portion extending upward from a bottom surface of the conductive contact plug; and
a third portion formed between and adjoining the first portion and the second portion, wherein the third portion tapers toward the first portion.

5. The contact structure as claimed in claim 1, wherein a cross-sectional profile of the first liner comprises:
an upper portion extending downward from a top surface of the first liner; and
a lower portion adjoining the upper portion of the first liner, wherein the lower portion of the first liner tapers downward.

6. The contact structure as claimed in claim 1, wherein a top surface of the first liner has a third width W3, and wherein the third width W3 is 3-10 nm.

7. The contact structure as claimed in claim 2, wherein a top surface of the first liner has a third width W3, and wherein a ratio W2/W3 of the second width W2 to the third width W3 is 5-40.

8. The contact structure as claimed in claim 1, wherein the first liner has a first height H1, wherein the conductive contact plug has a second height H2, and wherein a ratio H1/H2 of the first height H1 to the second height H2 is 0.1-0.8.

9. A method for forming a contact structure, comprising:
forming an insulating layer on a substrate;
performing a first etching process to form a contact hole in the insulating layer;
forming a first liner material on sidewalls and a bottom of the contact hole;
performing a second etching process to remove the first liner material on the bottom of the contact hole and to increase a depth of the contact hole, wherein the first liner material remaining on the sidewalls of the contact hole forms a first liner;
forming a second liner on the sidewalls and the bottom of the contact hole; and
filling a conductive material into the contact hole to form a conductive element on the substrate and in the insulating layer, wherein the second liner and the conductive element form a conductive contact plug, wherein the second liner is interposed between the conductive element and the first liner at an upper portion of the conductive element, and wherein the second liner is interposed between the conductive element and the insulating layer at a lower portion of the conductive element, and wherein a horizontal bottom portion of the second liner is interposed between the conductive element and the substrate.

10. The method for forming the contact structure as claimed in claim 9, further comprising performing at least one wet process after forming the first liner and before filling the conductive material.

11. The method for forming the contact structure as claimed in claim 10, wherein an etching rate of the insulating layer to an etching rate of the first liner is 10-100 during the at least one wet process.

12. The method for forming the contact structure as claimed in claim 9, wherein a bottom surface of the conductive contact plug has a first width W1, wherein a top surface of the conductive contact plug has a second width W2, and wherein the first width W1 is greater than or equal to the second width W2.

13. The method for forming the contact structure as claimed in claim 9, wherein before filling the conductive material, a cross-sectional profile of the contact hole comprises:
a first portion extending downward from a top surface of the contact hole;
a second portion extending upward from a bottom surface of the contact hole; and
a third portion formed between and adjoining the first portion and the second portion, wherein the third portion tapers toward the first portion.

14. The method for forming the contact structure as claimed in claim 9, wherein the first liner surrounds the upper portion of the conductive element.

15. (canceled)

16. The contact structure as claimed in claim 1, wherein the first liner includes silicon nitride, an oxynitride, a carbide, a polycrystalline silicon, another suitable insulating material, or a combination thereof.

17. A memory device, comprising:
a gate structure is formed on a substrate; and
two contact structures formed on the substrate and located on both sides of the gate structure, wherein a bottom surface of the contact structure is level with a bottom surface of the gate structure, and each of the contact structures comprises:
an insulating layer formed on a substrate;
a conductive element formed on the substrate and in the insulating layer;
a first liner formed in the insulating layer and on sidewalls of an upper portion of the conductive element; and
a second liner formed on the sidewalls of the conductive element, wherein the second liner and the conductive element form a conductive contact plug, wherein the second liner is interposed between the conductive element and the first liner at the upper portion of the conductive element, and wherein the second liner is interposed between the conductive element and the insulating layer at a lower portion of the conductive element, and wherein a horizontal bottom portion of the second liner is interposed between the conductive element and the substrate.

18. The memory device as claimed in claim 17, wherein a cross-sectional profile of the conductive contact plug comprises:
a first portion extending downward from a top surface of the conductive contact plug;
a second portion extending upward from a bottom surface of the conductive contact plug; and
a third portion formed between and adjoining the first portion and the second portion, wherein the third portion tapers toward the first portion.

19. The memory device as claimed in claim 17, wherein a cross-sectional profile of the first liner comprises:
an upper portion extending downward from a top surface of the first liner; and
a lower portion adjoining the upper portion of the first liner, wherein the lower portion of the first liner tapers downward.

20. The memory device as claimed in claim 17, wherein the first liner includes silicon nitride, an oxynitride, a carbide, a polycrystalline silicon, another suitable insulating material, or a combination thereof.
